(19) United States
(12) Patent Application Publication
(10) Pub. No.: US 2026/0143636 A1
(43) Pub. Date: May 21, 2026

(54) COLD PLATE DEVICE

(71) Applicants: INVENTEC (PUDONG) TECHNOLOGY CORPORATION, Shanghai (CN); INVENTEC CORPORATION, Taipei City (TW)

(72) Inventors: Hung-Ju CHEN, Taipei City (TW); Kai-Yang TUNG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/232,433

(22) Filed: Jun. 9, 2025

(30) Foreign Application Priority Data
Nov. 15, 2024 (CN) 202411644386.X

(51) Int. Cl. H05K 7/20

(52) U.S. Cl. CPC H05K 7/20327; H05K 7/20336

(57) ABSTRACT

A cold plate device includes a heat transfer housing, a set of fins, a fluid inlet pipe and a fluid outlet pipe. The heat transfer housing has a coolant space configured to contain the coolant. The fins are disposed on the heat transfer housing and in the coolant space. The fluid inlet pipe is connected to the heat transfer housing and communicated with the coolant space. The fluid inlet pipe includes a first widening portion and a first coupling portion. A width of the first widening portion gradually increases from the first coupling portion to the heat transfer housing. The fluid outlet pipe is connected to the heat transfer housing and communicated with the coolant space. The first widening portion corresponds to at least part of the fins. A widening direction of the first widening portion is non-parallel to an extension direction of the fins.

This application claims priority under 35 U.S.C. § 119(a) on Patent Application No(s). 202411644386.X filed in China on Nov. 15, 2024, the entire contents of which are hereby incorporated by reference.

### BACKGROUND

### 1. Technical Field

The present disclosure relates to a cold plate device, more particularly to a cold plate device including a fluid inlet pipe with widening portion.

### 2. Related Art

The operation of electronic devices generates a large amount of heat. If heat cannot be effectively removed, the internal electronic components will be overheated and cause malfunction or crash. Therefore, the electronic devices are usually equipped with a heat dissipation system to ensure that their operation will not exceed an estimated temperature. Especially, as to high-performance electronic devices such as servers, a liquid cooling system, such as a cold plate, can be used to provide better heat dissipation.

Generally, a structure for evenly distributing the coolant is provided at a fluid inlet of the cold plate to facilitate a uniform flow of the coolant at the fluid inlet for the improvement of heat dissipation efficiency. However, some regions of a conventional cold plate where fins can be provided is used to set up said structure, that is, the structure is provided by reducing the regions for mounting the fins. Since the regions for mounting the fins are reduced, the heat exchange area is reduced, causing the heat dissipation capability of the cold plate to be insufficient, thereby deteriorating the heat dissipation efficiency. Accordingly, it is a problem to be solved that the heat dissipation efficiency of the cold plate device should be improved.

### SUMMARY

According to one embodiment of the present disclosure, a cold plate device, configured to contain a coolant, includes a heat transfer housing, a set of fins, a fluid inlet pipe and a fluid outlet pipe. The heat transfer housing has a coolant space configured to contain the coolant. The fins are disposed on the heat transfer housing and in the coolant space. The fluid inlet pipe is connected to a side of the heat transfer housing away from the fins and communicated with the coolant space. The fluid inlet pipe includes a first widening portion and a first coupling portion. Opposite sides of the first widening portion are connected to the heat transfer housing and the first coupling portion, respectively. A width of the first widening portion gradually increases in a direction from the first coupling portion to the heat transfer housing. The fluid outlet pipe is connected to a side of the heat transfer housing away from the fins and communicated with the coolant space. The first widening portion corresponds to at least part of the fins. A widening direction of the first widening portion is non-parallel to an extension direction of the fins.

### BRIEF DESCRIPTION OF THE DRAWINGS

FIG. 1 is a perspective view of a cold plate device according to a first embodiment of the present disclosure;

FIG. 2 is a top view of the cold plate device in FIG. 1;

FIG. 3 is an exploded view of the cold plate device in FIG. 1;

FIG. 4 is a cross-sectional view of the cold plate device along cutting line 4-4 in FIG. 2;

FIG. 5 is another cross-sectional view of the cold plate device along cutting line 5-5 in FIG. 2;

FIG. 6 is a cross-sectional view of the cold plate device in FIG. 1;

FIG. 7 is a perspective view of a cold plate device according to a second embodiment of the present disclosure;

FIG. 8 is an exploded view of the cold plate device in FIG. 7;

FIG. 9 is a cross-sectional view of the cold plate device in FIG. 7;

FIG. 10 is a perspective view of a cold plate device according to a third embodiment of the present disclosure;

FIG. 11 is an exploded view of the cold plate device in FIG. 10; and

FIG. 12 is a cross-sectional view of the cold plate device in 10.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present disclosure. The following embodiments further illustrate various aspects of the present disclosure, but are not meant to limit the scope of the present disclosure.

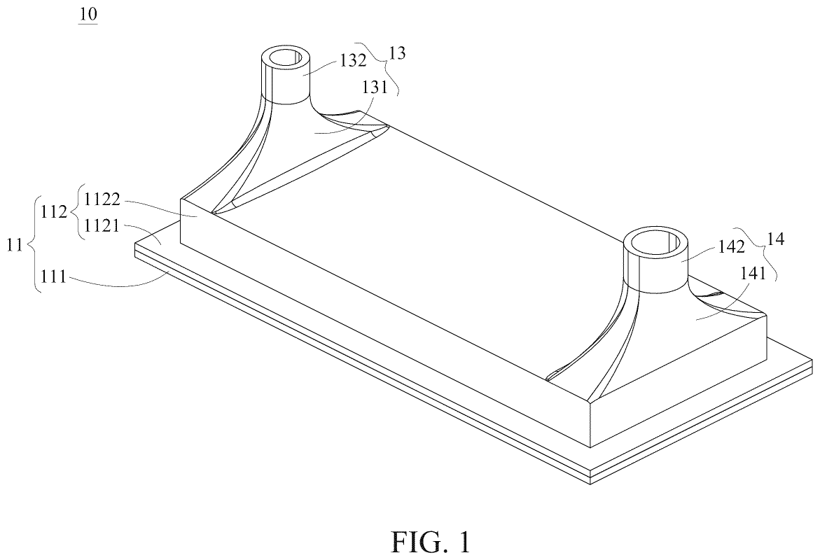

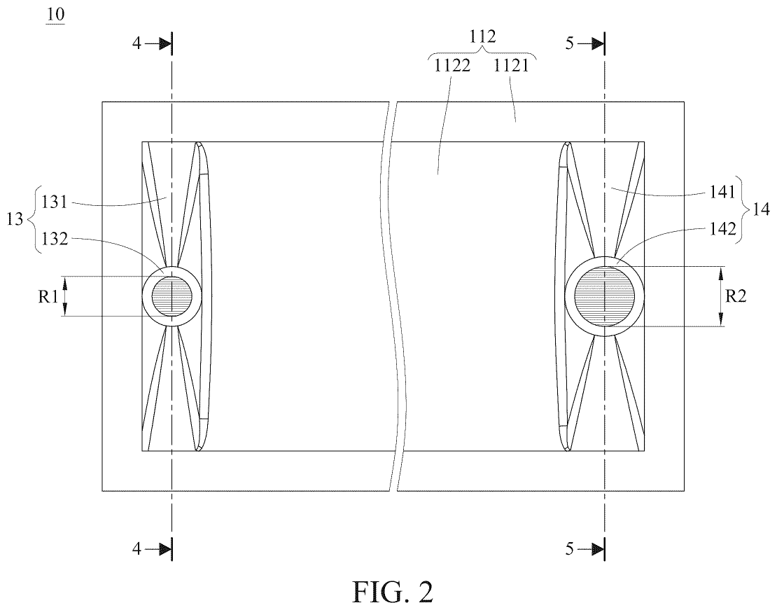

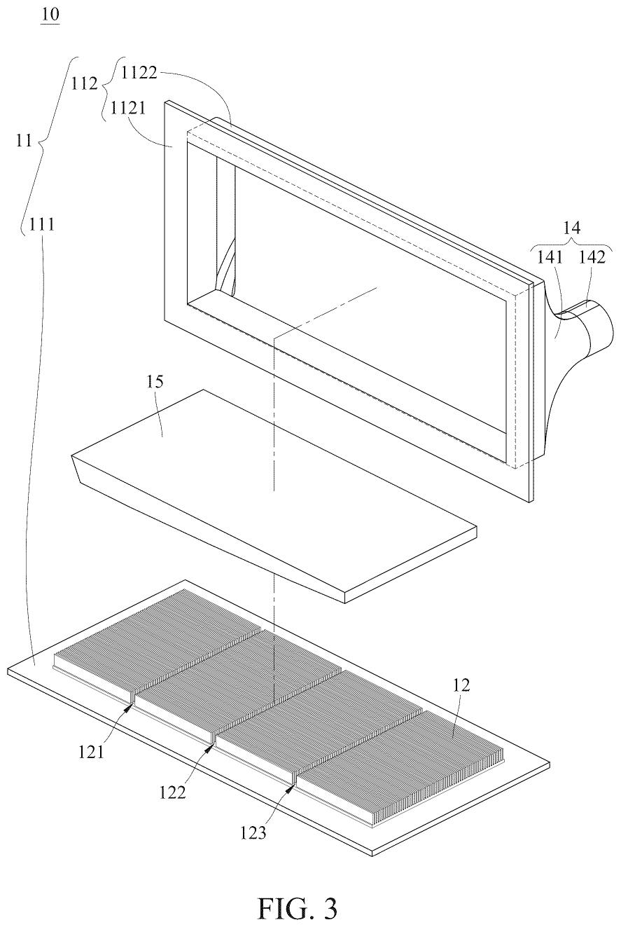

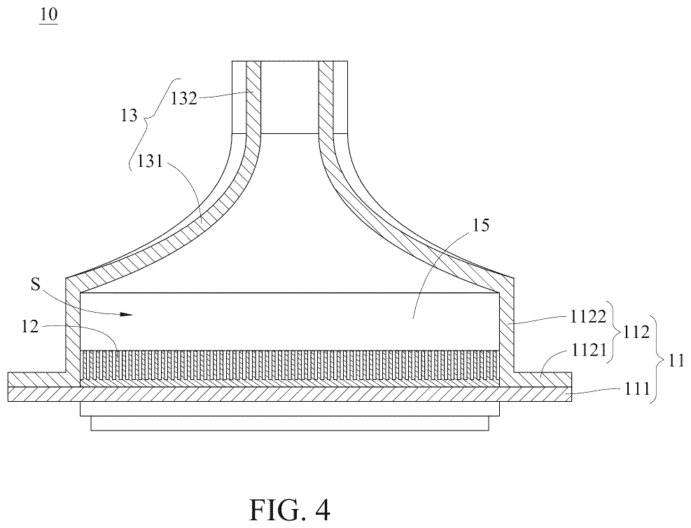

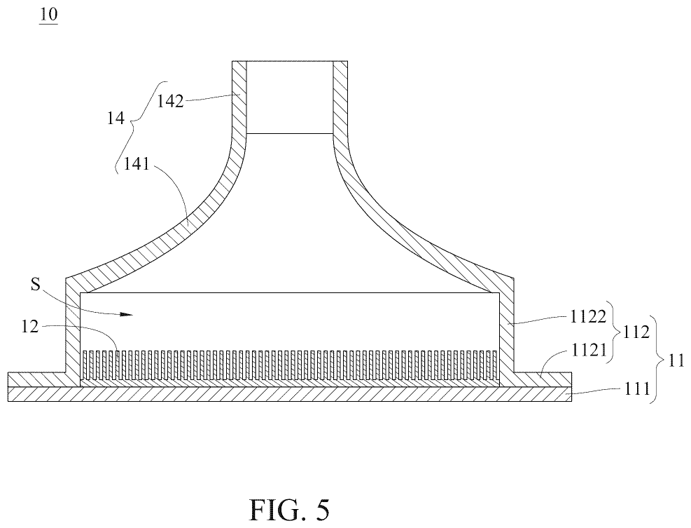

Please refer to FIG. 1 through FIG. 5. FIG. 1 is a perspective view of a cold plate device according to a first embodiment of the present disclosure. FIG. 2 is a top view of the cold plate device in FIG. 1. FIG. 3 is an exploded view of the cold plate device in FIG. 1. FIG. 4 is a cross-sectional view of the cold plate device along cutting line 4-4 in FIG. 2. FIG. 5 is another cross-sectional view of the cold plate device along cutting line 5-5 in FIG. 2.

The cold plate device 10 according to this embodiment is configured to contain a coolant such as water or refrigerant, and the cold plate device 10 is thermally coupled to a heat source (not shown in the drawings). The cold plate device 10 includes a heat transfer housing 11, a set of fins 12, a fluid inlet pipe 13, a fluid outlet pipe 14 and a first block 15. The heat transfer housing 11 includes a first housing 111 and a second housing 112. The first housing 111 and the second housing 112 together form a coolant space S for containing the coolant. The fins 12 are disposed on the first housing 111 and in the coolant space S. The second housing 112 includes a base 1121 and a protrusion 1122. The protrusion 1122 and the first housing 111 are connected to opposite sides of the base 1121, respectively.

The fluid inlet pipe 13 is connected to the second housing 112; that is, the fluid inlet pipe 13 is connected to the side of the heat transfer housing 11 away from the fins 12 and communicated with the coolant space S. Specifically, the fluid inlet pipe 13 includes a first widening portion 131 and a first coupling portion 132. Opposite sides of the first widening portion 131 are connected to the protrusion 1122 of the second housing 112 and the first coupling portion 132, respectively. A width of the first widening portion 131 gradually increases in a direction from the first coupling portion 132 to the protrusion 1122 of the second housing 112. The design of gradual widening for the first widening portion 131 is favorable for a uniform flow of the coolant into the coolant space S through the fluid inlet pipe 13.

Herein, the long edge of the first widening portion 131 is flush with the edge of the protrusion 1122 of the second housing 112. Also, the first widening portion 131 corresponds to at least part of the fins 12. That is, the fluid inlet pipe 13 is located above the fins 12. Moreover, a widening direction of the first widening portion 131 is non-parallel to an extension direction of the fins 12. For example, the widening direction of the first widening portion 131 is orthogonal to the extension direction of the fins 12.

The fluid outlet pipe 14 is connected to the second housing 112; that is, the fluid outlet pipe 14 is connected to the side of the heat transfer housing 11 away from the fins 12 and communicated with the coolant space S. Specifically, the fluid outlet pipe 14 includes a second widening portion 141 and a second coupling portion 142. Opposite sides of the second widening portion 141 are connected to the protrusion 1122 of the second housing 112 and the second coupling portion 142, respectively. A width of the second widening portion 141 gradually increases in a direction from the second coupling portion 142 to the protrusion 1122 of the second housing 112. The design of gradual widening for the second widening portion 141 is favorable for a uniform flow of the coolant out from the coolant space S.

Herein, the long edge of the second widening portion 141 is flush with the edge of the protrusion 1122 of the second housing 112. Also, the second widening portion 141 corresponds to at least part of the fins 12. That is, the fluid outlet pipe 14 is located above the fins 12. Moreover, a widening direction of the second widening portion 141 is non-parallel to the extension direction of the fins 12. For example, the widening direction of the second widening portion 141 is orthogonal to the extension direction of the fins 12.

Moreover, a diameter R2 of the second coupling portion 142 is greater than a diameter R1 of the first coupling portion 132. Since the liquid coolant flowing in the coolant space S absorbs heat from the heat source, the liquid coolant will transform into a gaseous coolant. The density of the gaseous coolant is greater than the density of the liquid coolant, such that the volume flow rate of the coolant at the fluid outlet pipe 14 is greater than the volume flow rate of the coolant at the fluid inlet pipe 13. Accordingly, the second coupling portion 142 with greater diameter R2 than the first coupling portion 132 with smaller diameter R1 is favorable for reducing the flow rate of the coolant at the fluid outlet pipe 14, thereby preventing corrosion/erosion to the cold plate device 10 due to overly high flow rate of the coolant at the fluid outlet pipe 14.

The first block 15 is disposed on the protrusion 1122 of the second housing 112 and in the coolant space S. Herein, the first block 15 and the protrusion 1122 are, for example, two independent elements. A distance between the fins 12 and the first block 15 gradually increases in a direction from the fluid inlet pipe 13 to the fluid outlet pipe 14. That is, the space between the fins 12 and the first block 15 enlarges in the direction from the fluid inlet pipe 13 to the fluid outlet pipe 14, such that the flow resistance of the coolant near the fluid outlet pipe 14 is smaller than the flow resistance of the coolant near the fluid inlet pipe 13. Thus, the coolant can be driven to flow toward the fluid outlet pipe 14 to prevent the reduction of heat dissipation efficiency due to coolant flow back.

Herein, the set of fins 12 includes a first groove 121, a second groove 122 and a third groove 123. After the liquid coolant absorbs heat transferred from the heat source to the heat transfer housing 11 at the fins 12 and become the gaseous coolant, the gaseous coolant can leave the fins from the first groove 121, the second groove 122 and the third groove 123.

The first groove 121, the second groove 122 and the third groove 123 correspond to the first block 15 and define a first section A1, a second section A2, a third section A3 and a fourth section A4 of the first block 15. The first section A1, the second section A2, the third section A3 and the fourth section A4 are sequentially arranged in the direction from the fluid inlet pipe 13 to the fluid outlet pipe 14. The joint between the first section A1 and the second section A2 is flush with the side of the first groove 121 close to the fluid inlet pipe 13, such that the liquid coolant is prevented from flowing away from the fins 12 through the first groove 121, which prevents a local dry heating due to insufficient liquid coolant at the fins 12.

One side of the second section A2 close to the fins 12, one side of the third section A3 close to the fins 12, and one side of the fourth section A4 close to the fins 12 each have an inclined face. The slope of the inclined face of the second section A2 close to the fins 12, the slope of the inclined face of the third section A3 close to the fins 12, and the slope of the inclined face of the fourth section A4 close to the fins 12 sequentially increase. That is, the closer to the downstream of the gaseous coolant flow, the greater the slope of the inclined face of corresponding section close to the fins 12, that is, the larger the space above the fins 12. Since the flow rate of the gaseous coolant increases nonlinearly with the increase of the flow path length, this design provides enough space for the gaseous coolant to flow, thereby preventing the reduction of heat dissipation efficiency.

One side of the first section A1 away from the second section A2 is, for example, inclined from the end away from the fins 12 in a direction away from the first widening portion, so as to guide the coolant from the fluid inlet pipe 13 into the coolant space S. One side of the fourth section A4 away from the third section A3 is flush with an inner face of the second widening portion 141. Herein, the side of the fourth section A4, flush with the inner face of the second widening portion 141, is, for example, vertical and not inclined. Therefore, in addition to simplifying the structural design of the second housing 112, the height above the fins 12 can also be decreased to reduce the space above the fins 12. It is favorable for preventing the liquid coolant from flowing from the fins 12 to the space above the fins 12 where the gaseous coolant flows, thereby preventing a local dry heating due to insufficient liquid coolant at the fins 12.

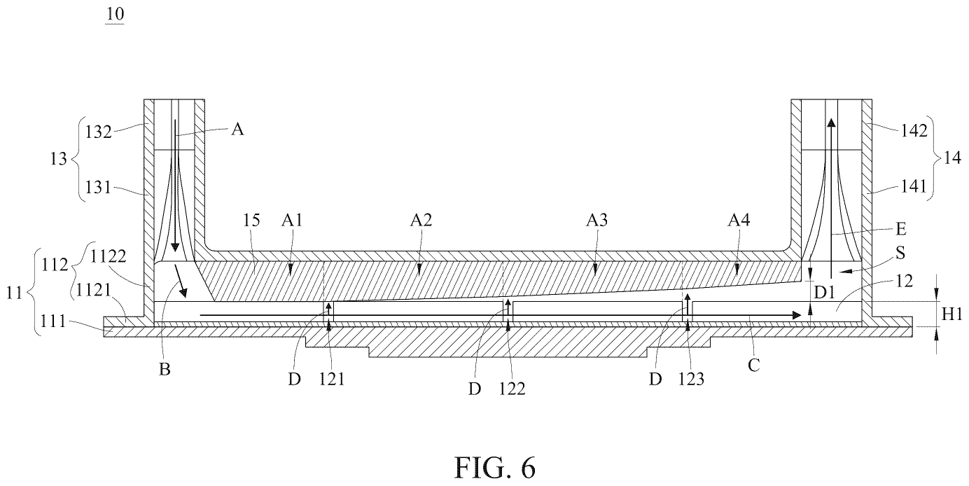

FIG. 6 is a cross-sectional view of the cold plate device in FIG. 1. A distance D1 between the side of the fourth section A4 close to the fluid outlet pipe 14 and the fins 12, for example, is less than half of the height H1 of the fins o as to reduce the space above the fins 12. Therefore, it is favorable for further preventing the liquid coolant from flowing from the fins 12 to the space above the fins 12 where the gaseous coolant flows, thereby preventing a local dry heating due to insufficient liquid coolant at the fins 12.

In this embodiment, the fluid inlet pipe 13 is provided with a first widening portion 131 with gradually widening width, such that the coolant can flow into the coolant space S more evenly through the first widening portion 131. The first widening portion 131 corresponds to at least part of the fins 12, that is the fluid inlet pipe 13 is located above the fins 12, such that the fins 12 are distributed over the first housing 111 without removing any fins 12, which eliminates the need for additional space on the first housing 111 to set up a structure for uniform coolant flow, thereby preventing the lack of heat removal capability of the cold plate due to the reduction of heat exchange area. Thus, the heat dissipation efficiency of the cold plate device 10 is enhanced.

Moreover, in the coolant space S of the cold plate device 10, the slopes of the inclined faces of the second through the fourth sections A2, A3, A4 close to the fins 12 sequentially increase. That is, the closer to the downstream of the gaseous coolant flow, the larger the space above the fins 12. This design provides the cold plate device 10 with enough internal space for the gaseous coolant flow, thereby preventing the reduction of heat dissipation efficiency.

In this embodiment, the first block 15 and the protrusion 1122 are two independent elements, but the present disclosure is not limited thereto. In some other embodiments, the first block and the protrusion may be integrally formed.

In this embodiment, the sides of the second through the fourth sections A2, A3, A4 close to the fins 12 are inclined planar surface, but the present disclosure is not limited thereto. In some other embodiments, the sides of the second through fourth sections close to the fins may be inclined curved surface.

In this embodiment, the cold plate device 10 is thermally coupled to a heat source to dissipate heat generated by the same. As shown in FIG. 6, when the liquid coolant flows through the fluid inlet pipe 13, the liquid coolant firstly flows along the direction A in the fluid inlet pipe 13 and is distributed in the first widening portion 131 to thereby into the coolant space S. Then, the liquid coolant flows to the fins 12 along the direction B by the guidance of the side of the first section A1 away from the second section A2.

Next, the liquid coolant flows at the fins 12 long the direction C and absorbs heat transferred from the heat source to the heat transfer housing 11. The liquid coolant absorbs heat source and evaporates to be gaseous coolant, and the gaseous coolant flows out of the fins 12 along the direction D though the first groove 121, the second groove 122 and the third groove 123. The gaseous coolant flows into the fluid outlet pipe 14 along the direction C through the space above the fins 12. Then, the gaseous coolant flows in the fluid outlet pipe 14 along the direction E and flows out of the fluid outlet pipe 14 so as to cool down the heat source for the next cooling cycle.

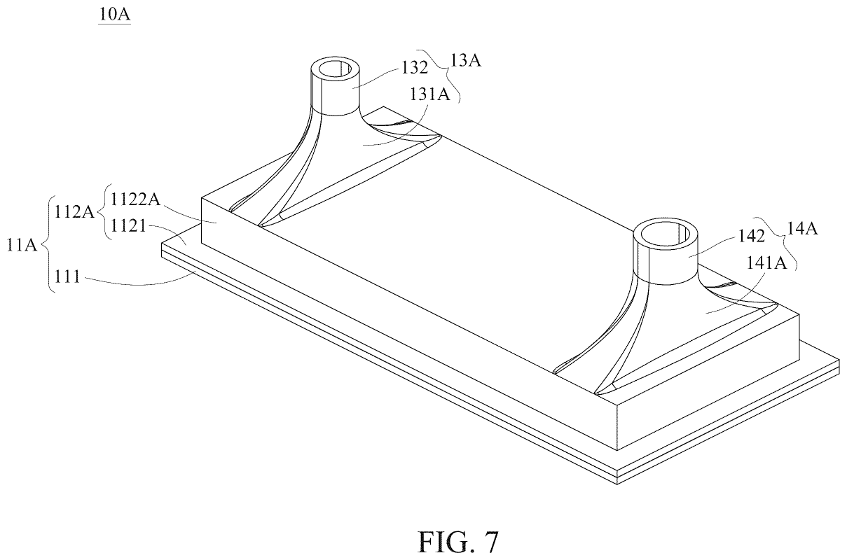

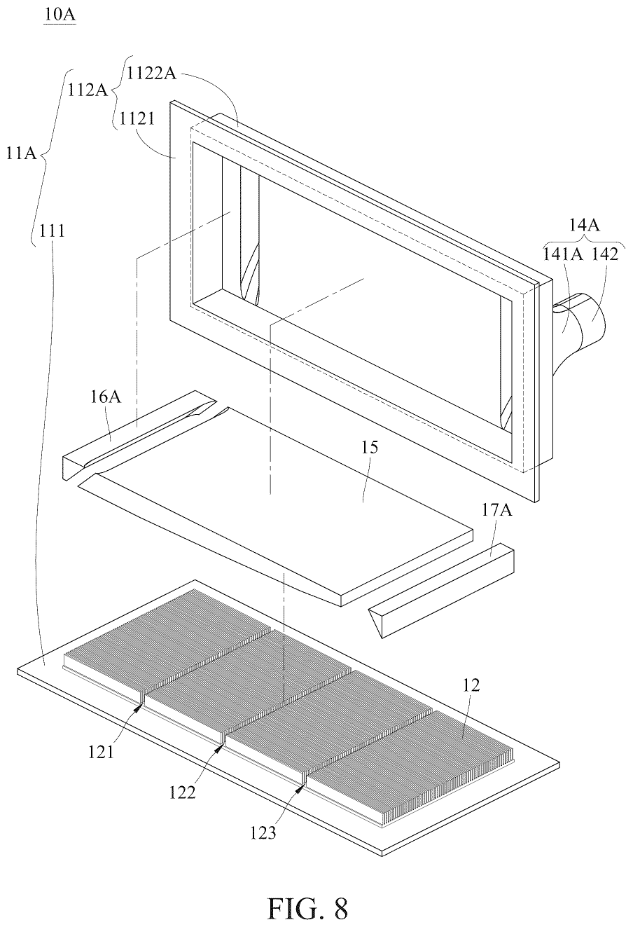

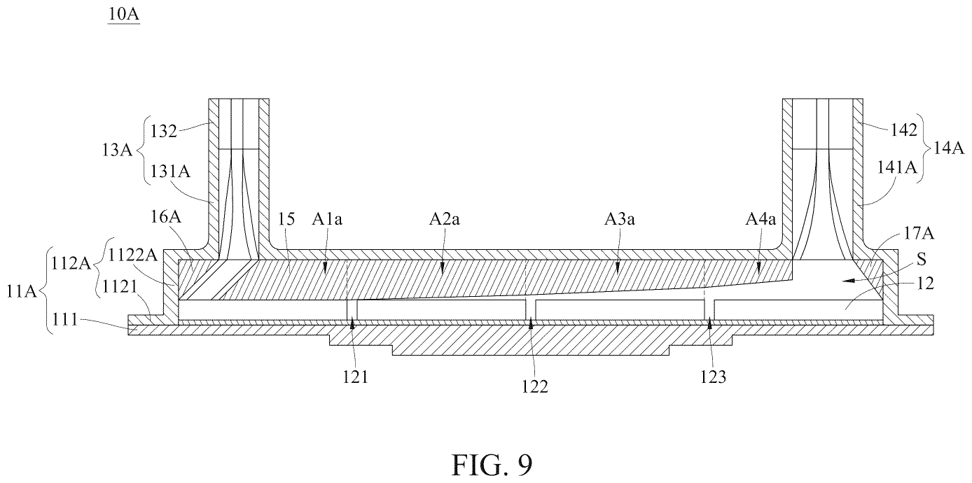

Please refer to FIG. 7 through FIG. 9. FIG. 7 is a perspective view of a cold plate device according to a second embodiment of the present disclosure. FIG. 8 is an exploded view of the cold plate device in FIG. 7. FIG. 9 is a cross-sectional view of the cold plate device in FIG. 7.

The cold plate device 10A according to this embodiment is similar to the cold plate device 10 of the first embodiment, such that the following mainly describes the differences between the two embodiments, and the description for similarities will be omitted. In this embodiment, the long edge of the first widening portion 131A of the fluid inlet pipe 13A and the long edge of the second widening portion 141A of the fluid outlet pipe 14A are separated from the edge of the protrusion 1122A of the second housing 112A. Also, the cold plate device 10A includes a second block 16A and a third block 17A. The second block 16A and the third block 17A are disposed in the coolant space S. The second block 16A is disposed at the edge of the protrusion 1122A of the second housing 112A close to the first widening portion 131A. The third block 17A is disposed at the edge of the second housing 112A close to the second widening portion 141A. The second block 16A, the third block 17A and the protrusion 1122A are, for example, three independent elements.

One side of the first section A1a away from the second section A2a is inclined from the end away from the fins 12 in a direction away from the fluid outlet pipe 14A. One side of the second block 16A close to the first block 15 is inclined such that the side of the second block 16A close to the first block 15 and the side of the first section A1a away from the second section A2a together guide the coolant to flow into the coolant space S through the fluid inlet pipe 13A. Specifically, this design allows the coolant to flow from the outermost side of the fins 12 in the coolant space S, such that the coolant space S can be fully utilized to prevent the reduction of heat dissipation efficiency. Herein, the slope of the inclined face of the second block 16A close to the first block 15 is the same as the slope of the inclined face of the first section A1a away from the second section A2a. On the other hand, one side of third block 17A close to the first block 15 is inclined from the end away from the fins 12 in a direction away from the fluid inlet pipe 13A so as to guide the coolant to flow out of the coolant space S through the fluid outlet pipe 14A.

In this embodiment, since the long edge of the first widening portion 131A and the long edge of the second widening portion 141A are separated from the edge of the protrusion 1122A, the coolant tends to be mixed flow or precipitate at the edge of the protrusion 1122A close to the first widening portion 131A so as to reduce heat dissipation efficiency. The second block 16A, disposed at the edge of the protrusion 1122A of the second housing 112A close to the first widening portion 131A, is favorable for the coolant to directly flow toward the fins so as to prevent the reduction of heat dissipation efficiency.

In this embodiment, the second block 16A and the protrusion 1122A are two independent elements, but the present disclosure is not limited thereto. In some other embodiments, the second block and the protrusion may be integrally formed.

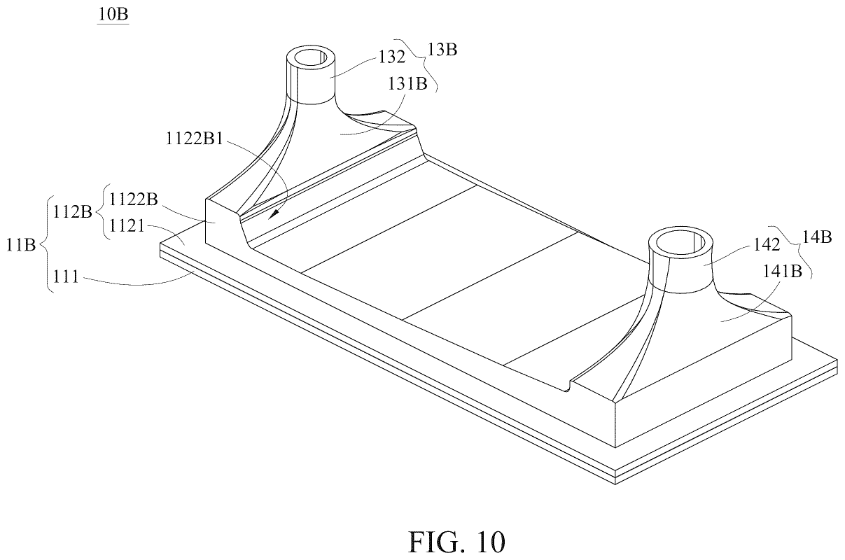

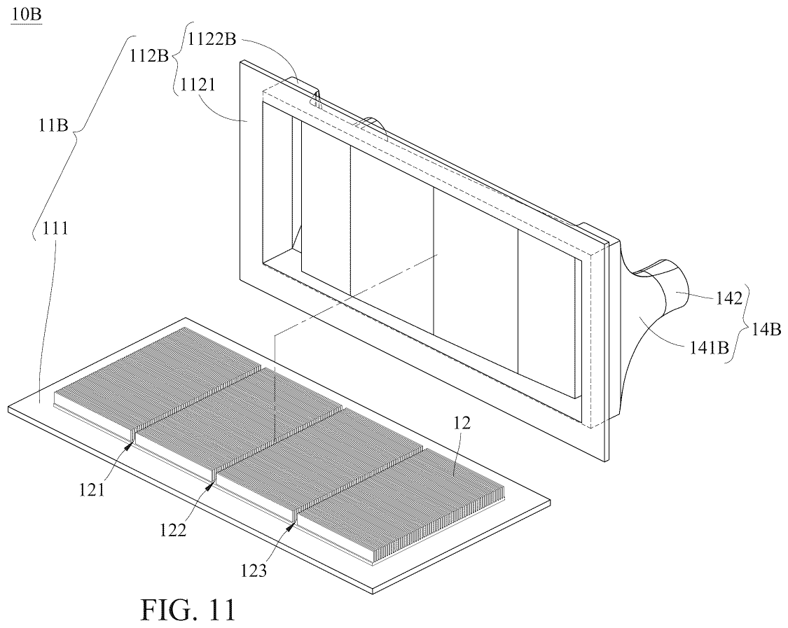

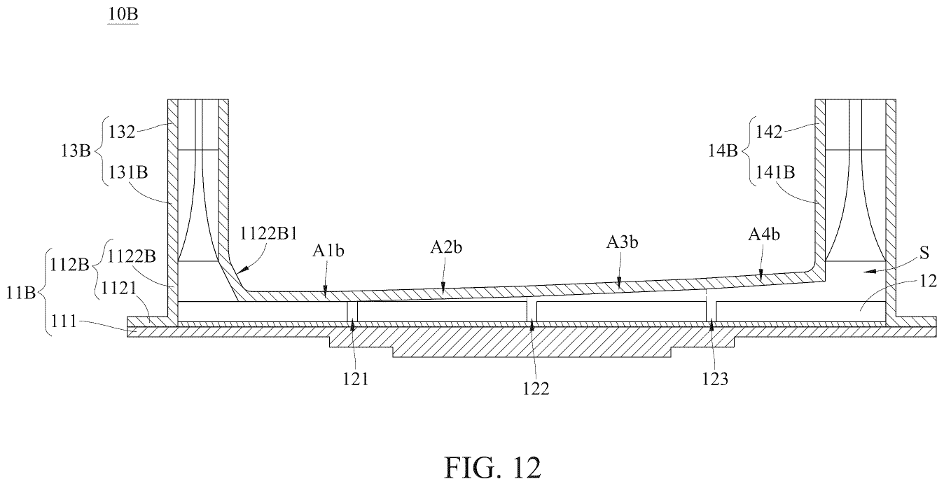

Please refer to FIG. 10 through FIG. 12. FIG. 10 is a perspective view of a cold plate device according to a third embodiment of the present disclosure. FIG. 11 is an exploded view of the cold plate device in FIG. 10. FIG. 12 is a cross-sectional view of the cold plate device in 10.

The cold plate device 10B according to this embodiment is similar to the cold plate device 10 of the first embodiment, such that the following mainly describes the differences between the two embodiments, and the description for similarities will be omitted. In this embodiment, the cold plate device 10B does not include first block. Thus, it is favorable for decreasing the number of elements in the cold plate device 10B so as to reduce the weight of the cold plate device 10B.

Since the cold plate device 10B includes no first block, the distance between the fins 12 and the protrusion 1122B of the second housing 112B gradually increases in a direction from the fluid inlet pipe 13B to the fluid outlet pipe 14B. The first through third grooves 121, 122, 123 of the fins 12 correspond to the protrusion 1122B, and can define a first section A1b, a second section A2b, a third section A3b and a fourth section A4b of the protrusion 1122B. Also, the protrusion 1122B includes an inclined portion 1122B1 obliquely between the first widening portion 131B of the fluid inlet pipe 13B and the first section A1b. The inclined portion 1122B1 is favorable for guiding the coolant to flow into the coolant space S through the fluid inlet pipe 13B.

In this embodiment, the servers may be used for artificial intelligence (AI) computing, edge computing, and also be served as 5G servers, cloud servers, or Internet of Vehicles servers.

According to the present disclosure, the fluid inlet pipe is provided with a first widening portion with gradually widening width, such that the coolant can flow into the coolant space more evenly through the first widening portion. The first widening portion corresponds to at least part of the fins, that is the fluid inlet pipe is located above the fins, such that the fins are distributed over the first housing without removing any fins, which eliminates the need for additional space on the first housing to set up a structure for uniform coolant flow, thereby preventing the lack of heat removal capability of the cold plate due to the reduction of heat exchange area. Thus, the heat dissipation efficiency of the cold plate device is enhanced.

Furthermore, in the coolant space of the cold plate device, the slopes of the inclined faces of the second through the fourth sections close to the fins sequentially increase. That is, the closer to the downstream of the gaseous coolant flow, the larger the space above the fins. This design provides the cold plate device with enough internal space for the gaseous coolant flow, thereby preventing the reduction of heat dissipation efficiency.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A cold plate device, configured to contain a coolant, comprising:
a heat transfer housing having a coolant space configured to contain the coolant;
a set of fins, disposed on the heat transfer housing and in the coolant space;
a fluid inlet pipe, connected to a side of the heat transfer housing away from the set of fins and communicated with the coolant space, wherein the fluid inlet pipe comprises a first widening portion and a first coupling portion, opposite sides of the first widening portion are respectively connected to the heat transfer housing and the first coupling portion, a width of the first widening portion gradually increases in a direction from the first coupling portion to the heat transfer housing, the first widening portion corresponds to at least part of the set of fins, and a widening direction of the first widening portion is non-parallel to an extension direction of the set of fins; and
a fluid outlet pipe, connected to a side of the heat transfer housing away from the set of fins and communicated with the coolant space.

2. The cold plate device according to claim 1, wherein the fluid outlet pipe comprises a second widening portion and a second coupling portion, opposite sides of the second widening portion are respectively connected to the heat transfer housing and the second coupling portion, a width of the second widening portion gradually increases in a direction from the second coupling portion to the heat transfer housing, the second widening portion corresponds to at least another part of the set of fins, a widening direction of the second widening portion is non-parallel to the extension direction of the set of fins, and a diameter of the second coupling portion is greater than a diameter of the first coupling portion.

3. The cold plate device according to claim 2, wherein the heat transfer housing comprises a first housing and a second housing, the first housing and the second housing together form the coolant space, the first widening portion of the fluid inlet pipe and the second widening portion of the fluid outlet pipe are connected to the second housing, and the set of fins is disposed on the first housing.

4. The cold plate device according to claim 3, wherein the second housing includes a base and a protrusion, the protrusion and the first housing are respectively connected to opposite sides of the base, the first widening portion of the fluid inlet pipe and the second widening portion of the fluid outlet pipe are connected to the protrusion, and a distance between the set of fins and the protrusion gradually increases in a direction from the fluid inlet pipe to the fluid outlet pipe.

5. The cold plate device according to claim 4, wherein the set of fins comprises a first groove, a second groove and a third groove, the first groove, the second groove and the third groove correspond to the protrusion and define a first section, a second section, a third section and a fourth section of the protrusion, the first section, the second section, the third section and the fourth section are sequentially arranged in the direction from the fluid inlet pipe to the fluid outlet pipe, a joint between the first section and the second section is flush with a side of the first groove close to the fluid inlet pipe, a side of the second section, a side of the third section and a side of the fourth section close to the set of fins each have an inclined face, and slopes of the inclined faces of the second section, the third section and the fourth section sequentially increase.

6. The cold plate device according to claim 5, wherein a long edge of the first widening portion of the fluid inlet pipe and a long edge of the second widening portion of the fluid outlet pipe are flush with an edge of the second housing, the protrusion comprises an inclined portion, and the inclined portion is obliquely between the first widening portion of the fluid inlet pipe and the first section.

7. The cold plate device according to claim 3, further comprising a first block disposed on the second housing and in the coolant space, wherein a distance between the set of fins and the first block gradually increases in a direction from the fluid inlet pipe to the fluid outlet pipe.

8. The cold plate device according to claim 7, wherein the set of fins comprises a first groove, a second groove and a third groove, the first groove, the second groove and the third groove correspond to the first block and define a first section, a second section, a third section and a fourth section of the first block, the first section, the second section, the third section and the fourth section are sequentially arranged in the direction from the fluid inlet pipe to the fluid outlet pipe, a joint between the first section and the second section is flush with a side of the first groove close to the fluid inlet pipe, a side of the second section, a side of the third section and a side of the fourth section close to the set of fins each have an inclined face, and slopes of the inclined faces of the second section, the third section and the fourth section sequentially increase.

9. The cold plate device according to claim 8, wherein a long edge of the first widening portion of the fluid inlet pipe and a long edge of the second widening portion of the fluid outlet pipe are flush with an edge of the second housing, a side of the first section away from the second section is inclined in a direction away from the first widening portion, and a side of the fourth section away from the third section is flush with an inner face of the second widening portion.

10. The cold plate device according to claim 8, further comprising a second block and a third block, wherein a long edge of the first widening portion of the fluid inlet pipe and a long edge of the second widening portion of the fluid outlet pipe are separated from an edge of the second housing, the second block and the third block are disposed in the coolant space, the second block is disposed at an edge of the second housing close to the first widening portion, the third block is disposed at an edge of the second housing close to the second widening portion, a side of the first section away from the second section is inclined in a direction away from the fluid outlet pipe, a side of the second block close to the first block is inclined, and a slope of the side of the second block close to the first block is same as a slope of the side of the first section away from the second section, a side of the third block close to the first block is inclined in a direction away from the fluid inlet pipe, and a side of the fourth section away from the third section is flush with an inner face of the second widening portion.
